(19) United States
(12) Patent Application Publication
(10) Pub. No.: US 2021/0055457 A1
(43) Pub. Date: Feb. 25, 2021

(54) COLOR FILTER MANUFACTURING METHOD, COLOR FILTER, AND RESIN COMPOSITION

(71) Applicant: TOKYO OHKA KOGYO CO., LTD., Kawasaki-shi (JP)

(72) Inventors: Takehiro Seshimo, Kawasaki-shi (JP); Hiroaki Takeuchi, Kawasaki-shi (JP); Tomoyuki Inoue, Kawasaki-shi (JP)

(21) Appl. No.: 16/983,230

(22) Filed: Aug. 3, 2020

(30) Foreign Application Priority Data
Aug. 19, 2019 (JP) 2019-150047

(51) Int. Cl. G02B 1/04; C08F 220/28; G02B 5/20

(52) U.S. Cl. CPC G02B 1/04; G02B 5/201; C08F 220/281

(57) ABSTRACT

A color filter manufacturing method that forms low refractive index partition walls using a material easily removable by asking without the need to use fluororesin as a partition wall material; a color filter as a product by such a color filter manufacturing method; and a resin composition suitable for use in such a color filter manufacturing method. The method includes forming partition walls using a bubble-containing resin or resin composition containing bubbles, or the like, and having an inorganic content of 5% by mass or less.

This application claims priority to Japanese Patent Application No. 2019-150047 filed Aug. 19, 2019, the entire content of which is incorporated herein by reference.

### BACKGROUND OF THE INVENTION

### Field of the Invention

The present invention relates to a color filter manufacturing method, a color filter obtained by the color filter manufacturing method, and a resin composition suitable for use in the color filter manufacturing method.

### Related Art

A color filter used for a variety of image displays such as solid-state imaging devices and liquid crystal displays in the related art includes colored layers such as layers of red (R), green (G), and blue (B) in a matrix arrangement; and partition walls that separate the colored layers.

For example, such a color filter, proposed for use in solid-state imaging devices, includes colored layers in a matrix arrangement; and lower refractive index layers that include fluororesin and serve as partition walls to separate the colored layers (see Patent Document 1). Such a color filter can be manufactured by a simplified manufacturing process and can reduce color mixing caused by light obliquely incident on the color filter well.

Patent Document 1: Japanese Unexamined Patent Application, Publication No. 2006-295125

### SUMMARY OF THE INVENTION

Unfortunately, the color filter disclosed in Patent Document 1 has a disadvantage caused by highly liquid-repellent fluororesin used to form the partition walls, although it can be advantageously manufactured by the simplified manufacturing process. Specifically, Patent Document 1 discloses a method that includes filling gaps between colored layers in a matrix arrangement with a fluororesin-containing coating liquid using spin coating to form partition walls. Unfortunately, in the method disclosed in Patent Document 1, the liquid repellency of fluororesin may inhibit smooth infiltration of the fluororesin-containing coating liquid into the gaps depending on the gap size.

In addition, the partition wall material is required not only to have a low refractive index but also to be easily removable by asking so that it can be easily removed if any defects occur during the partition wall forming process or the color filter forming process.

The present invention has been made in light of the problems mentioned above. It is an object of the present invention to provide a color filter manufacturing method that makes it possible to form low refractive index partition walls using a material easily removable by asking without the need to use fluororesin as a partition wall material; to provide a color filter as a product by such a color filter manufacturing method; and to provide a resin composition suitable for use in such a color filter manufacturing method.

The present inventors have completed the present invention based on the findings that the above problems can be solved when partition walls are formed using a resin or resin composition containing bubbles and having an inorganic content of 5% by mass or less.

A first aspect of the present invention is directed to a method of manufacturing a color filter including a substrate; light-transmitting colored layers; and partition walls, the light-transmitting colored layers and the partition walls being provided on the substrate, each partition wall being disposed between and in contact with two of the colored layers adjacent to the partition wall to separate the adjacent colored layers with no gap between each of the adjacent colored layers and the partition wall, the partition wall having a refractive index lower than that of the colored layer, the method including:

forming plural colored layers such that the plural colored layers are arranged with gaps each at a position where a partition wall is to be formed; and
filling the gaps with a bubble-containing resin, a bubble-containing resin composition, a bubble-containing cured resin, or a bubble-containing cured resin composition to form partition walls,
the resin, the resin composition, the cured resin, or the cured resin composition having an inorganic content of 5% by mass or less.

A second aspect of the present invention is directed to a method of manufacturing a color filter including a substrate; light-transmitting colored layers; and partition walls, the light-transmitting colored layers and the partition walls being provided on the substrate, each partition wall being disposed between and in contact with two of the colored layers adjacent to the partition wall to separate the adjacent colored layers with no gap between each of the adjacent colored layers and the partition wall, the partition wall having a refractive index lower than that of the colored layer, the method including:

forming a partition wall precursor film on the substrate; forming, on the precursor film, a mask at a position where each partition wall is to be formed;
subjecting the mask and the precursor film to an asking treatment to remove portions of the precursor film not covered by the mask and to retain, as a partition wall, each of portions of the precursor film covered by the mask; removing the mask; and
forming a colored layer in each of regions separated by the partition walls,
the precursor film including a bubble-containing resin, a bubble-containing resin composition, a bubble-containing cured resin, or a bubble-containing cured resin composition, the resin, the resin composition, the cured resin, or the cured resin composition having an inorganic content of 5% by mass or less.

A third aspect of the present invention is directed to a color filter including: a substrate; light-transmitting colored layers; and partition walls, the light-transmitting colored layers and the partition walls being provided on the substrate, each partition wall being disposed between and in contact with two of the colored layers adjacent to the partition wall to separate the adjacent colored layers with no gap between each of the adjacent colored layers and the partition wall, the partition wall having a refractive index lower than that of the colored layer,

the partition walls including a bubble-containing resin, a bubble-containing resin composition, a bubble-containing cured resin, or a bubble-containing cured resin composition, the resin, the resin composition, the cured resin, or the cured resin composition having an inorganic content of 5% by mass or less.

A fourth aspect of the present invention is directed to a resin composition for use in forming the partition walls or the precursor film or forming a cured product in the method according to the first or second aspect, the resin composition including (A) a resin and (B) hollow particles each having a shell including a resin, or

including (A) a resin, (B) hollow particles each having a shell including a resin, and (S) an organic solvent.

The present invention makes it possible to provide a color filter manufacturing method that makes it possible to form low refractive index partition walls using a material easily removable by asking without the need to use fluororesin as a partition wall material; to provide a color filter as a product by such a color filter manufacturing method; and to provide a resin composition suitable for use in such a color filter manufacturing method.

### BRIEF DESCRIPTION OF THE DRAWINGS

FIG. 1A and FIG. 1B are diagrams showing schematically a color filter manufacturing method according to a first embodiment; and

FIGS. 2A to 2E are diagrams showing schematically a color filter manufacturing method according to a second embodiment.

### DETAILED DESCRIPTION OF THE EMBODIMENTS

### First Embodiment

A first embodiment is directed to a method of manufacturing a color filter including:

a substrate; light-transmitting colored layers; and partition walls, the light-transmitting colored layers and the partition walls being provided on the substrate, each partition wall being disposed between and in contact with two of the colored layers adjacent to the partition wall to separate the adjacent colored layers with no gap between each of the adjacent colored layers and the partition wall, the partition wall having a refractive index lower than that of the colored layer, the method including:
forming plural colored layers such that the plural colored layers are arranged with gaps each at a position where a partition wall is to be formed; and
filling the gaps with a bubble-containing resin, a bubble-containing resin composition, a bubble-containing cured resin, or a bubble-containing cured resin composition to form partition walls,
the resin, the resin composition, the cured resin, or the cured resin composition having an inorganic content of 5% by mass or less.

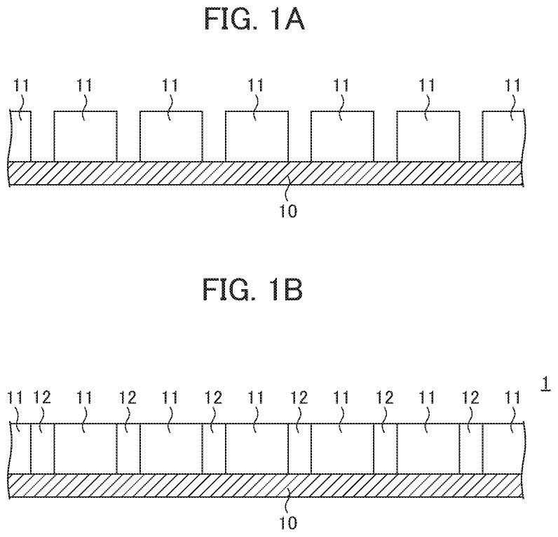

Hereinafter, the method of manufacturing a color filter according to the first embodiment will be described with reference to FIG. 1A and FIG. 1B.

### <Step of Forming Colored Layers>

As shown in FIG. 1A, according to the method, plural colored layers 11 are first formed on a substrate 10 such that they are arranged with gaps at positions where partition walls 12 are to be formed. The substrate 10 is not particularly limited and may be selected from known substrates depending on the type of a device for which a color filter 1 will be used.

Typically, a plurality of colored layers 11 of red (R), green (G), and blue (B), etc. are formed in a matrix arrangement on the substrate 10 according to the size of the substrate 10. Any method may be used to form the plurality of colored layers 11 in a matrix arrangement. A method of forming the colored layers 11 of red (R), green (G), and blue (B) in a matrix arrangement on the substrate 10 may include, for example, forming colored layers of each color by a photolithographic process using each of photosensitive compositions for the three colors: red (R), green (G), and blue (B) so that the colored layer forming process is performed three times.

The colored layers 11 may be formed with any thickness, which is appropriately determined taking into account the type, performance, and other features of the device for which the color filter 1 is to be used. The thickness of the colored layer 11 is preferably, for example, 0.1 μm or more and 10 μm or less, more preferably 0.5 μm or more and 5 μm or less.

The gap between the colored layers 11 may have any width, which is appropriately determined taking into account the type, performance, and other features of the device for which the color filter 1 is to be used. The width of the gap between the colored layers 11 is, for example, preferably 0.1 μm or more and 5 μm or less, more preferably 0.3 μm or more and 2 μm or less. When the width of the gap between the colored layers 11 is within the above range, the gap can be easily filled with the material for the partition walls 12 in the subsequent partition wall forming step.

### <Step of Forming Partition Walls>

As shown in FIG. 1B, the partition wall forming step includes filling the gaps between the colored layers 11, formed in the colored layer forming step, with a bubble-containing resin, a bubble-containing resin composition, a bubble-containing cured resin, or a bubble-containing cured resin composition to form partition walls 12. In this step, the resin, resin composition, cured resin, or cured resin composition, for use in filling the gaps, contains bubbles. Therefore, the partition walls 12 contain bubbles. The bubbles in the resin, resin composition, cured resin, or cured resin composition allow the formed partition walls 12 to have a refractive index lower than that of the colored layers.

The gaps may be filled with the resin or resin composition by filling the gaps with a liquid composition including the resin and a solvent and then removing the solvent by heating or other means. The resin in the liquid composition is preferably a fluorine-free resin so that the gaps can be easily filled with the resin or resin composition. Examples of the resin in the liquid composition include, but are not limited to, (meth)acrylic resin, polyester resin, polyamide resin, and cyclic olefin resin.

The resin or resin composition may be a product obtained by curing a curable material. In this case, the gaps may be filled with the cured resin or cured resin composition by filling the gaps with a liquid composition including an uncured resin precursor and then curing the liquid composition in the gap by heating, exposure to light, or other methods.

The curable material for use as the resin precursor may be any material that can form a light-transmitting cured product. The curable material may be a thermosetting material or a photocurable material. Further, the curable material is preferably used together with a curing agent if necessary. The curing agent may be a photosensitive curing agent or a thermosensitive curing agent.

Typical examples of thermosetting materials include isocyanate compounds, melamine compounds, oxetane compounds, and epoxy compounds. Among these, epoxy compounds and oxetane compounds are preferred, and epoxy compounds are more preferred because of their high curability. The epoxy compounds are preferably polyfunctional epoxy compounds. As used therein, the term “polyfunctional epoxy compound” refers to an epoxy compound having two or more epoxy groups per molecule.

Typical examples of photocurable materials include unsaturated double bond-containing compounds such as a variety of (meth) acrylates. Such photocurable compounds include monofunctional compounds and polyfunctional compounds.

Monofunctional compounds include (meth)acrylamide, methylol (meth) acrylamide, methoxymethyl (meth) acrylamide, ethoxymethyl (meth) acrylamide, propoxymethyl (meth) acrylamide, butoxymethoxymethyl (meth) acrylamide, N-methylol (meth) acrylamide, N-hydroxymethyl (meth) acrylamide, (meth)acrylic acid, fumaric acid, maleic acid, maleic anhydride, itaconic acid, itaconic anhydride, citraconic acid, citraconic anhydride, crotonic acid, 2-acrylamido-2-methylpropanesulfonic acid, tert-butylacrylamidosulfonic acid, methyl (meth)acrylate, ethyl (meth)acrylate, butyl (meth) acrylate, 2-ethylhexyl (meth) acrylate, cyclohexyl (meth) acrylate, 2-hydroxyethyl (meth) acrylate, 2-hydroxypropyl (meth) acrylate, 2-hydroxybutyl (meth) acrylate, 2-phenoxy-2-hydroxypropyl (meth) acrylate, 2-(meth)acryloyloxy-2-hydroxypropyl phthalate, glycerin mono(meth)acrylate, tetrahydrofurfuryl (meth) acrylate, N,N-dimethylaminoethyl (meth)acrylate, glycidyl (meth)acrylate, 2,2,2-trifluoroethyl (meth)acrylate, 2,2,3,3-tetrafluoropropyl (meth)acrylate, and half-(meth)acrylates of phthalic acid derivatives. These monofunctional compounds may be used alone, or two or more of them may be used in combination.

Polyfunctional compounds include ethylene glycol di(meth)acrylate, diethylene glycol di(meth)acrylate, tetraethylene glycol di(meth)acrylate, propylene glycol di(meth)acrylate, polypropylene glycol di(meth)acrylate, butylene glycol di(meth)acrylate, neopentyl glycol di(meth)acrylate, 1,6-hexane glycol di(meth)acrylate, trimethylolpropane tri(meth)acrylate, glycerin di(meth)acrylate, pentaerythritol triacrylate, pentaerythritol tetraacrylate, dipentaerythritol pentaacrylate, dipentaerythritol hexaacrylate, pentaerythritol di(meth)acrylate, pentaerythritol tri(meth)acrylate, pentaerythritol tetra(meth)acrylate, dipentaerythritol penta(meth)acrylate, dipentaerythritol hexa(meth)acrylate, 2,2-bis(4-(meth)acryloxydiethoxyphenyl)propane, 2,2-bis(4-(meth)acryloxypolyethoxyphenyl)propane, 2-hydroxy-3-(meth)acryloyloxypropyl (meth) acrylate, ethylene glycol diglycidyl ether di(meth)acrylate, diethylene glycol diglycidyl ether di(meth)acrylate, phthalic acid diglycidyl ester di(meth)acrylate, glycerin triacrylate, glycerin polyglycidyl ether poly(meth)acrylate, urethane (meth)acrylate (i.e., tolylene diisocyanate), reaction products of trimethylhexamethylene diisocyanate, hexamethylene diisocyanate, and 2-hydroxyethyl (meth)acrylate, methylene bis(meth)acrylamide, (meth) acrylamide methylene ether, polyfunctional compounds such as condensates of polyhydric alcohols and N-methylol(meth)acrylamide, and triacrylformal. These polyfunctional compounds may be used alone, or two or more of them may be used in combination.

The matrix including the resin, resin composition, cured resin, or cured resin composition may contain unshelled bubbles or shelled bubbles. The matrix including the resin, resin composition, cured resin, or cured resin composition preferably contains shelled bubbles, which makes it easy to adjust the size of bubbles and to disperse stable bubbles in the resin, resin composition, cured resin, or cured resin composition. The shelled bubbles may be formed in the resin, resin composition, cured resin, or cured resin composition by adding hollow particles to a resin or resin composition. As described later, the resin, resin composition, cured resin, or cured resin composition used to form the partition walls 12 contains only a small amount of an inorganic component. For this reason, the hollow particles to be used each preferably have a shell including a resin.

Examples of methods for including bubbles in the resin, resin composition, cured resin, or cured resin composition include a method using a well-known microbubble or nanobubble generator to blow very small bubbles into a liquid composition for use in forming the partition walls 12; and a method that includes adding a blowing agent to a liquid composition for use in forming the partition walls 12 and generating gas by thermal decomposition or chemical reaction of the blowing agent so that bubbles are formed in the liquid composition.

The partition walls 12 may have any bubble content which is appropriately determined taking into account what refractive index the partition walls 12 should have.

The resin, resin composition, cured resin, or cured resin composition used to form the partition walls 12 has an inorganic content of 5% by mass or less, preferably 3% by mass or less, more preferably 1% by mass or less, still more preferably 0% by mass. When the inorganic content is 5% by mass or less, the material used to form the partition walls 12 can be easily removed by ashing. The colored layers 11 may also contain no or almost no inorganic component. In this case, if any defects are found in the colored layers 11 or the partition walls 12 after the formation of the color filter 1, the colored layers 11 and the partition walls 12 can be removed by ashing so that the substrate 10 can be reused. On the other hand, if the resin, resin composition, cured resin, cured resin composition used to form the partition walls 12 contains a large amount of inorganic components, the partition walls 12 will be difficult to remove by ashing since the inorganic components will produce a large amount of residue.

For the same reason as mentioned for the partition walls 12, the colored layers 11 are also preferably free of an inorganic component, such as copper phthalocyanine, so that they can be easily subjected to ashing.

The ashing may be performed by any method that will not cause an unacceptable level of damage to the substrate 10. A preferred ashing treatment method may be a method using an oxygen plasma. Subjecting the colored layers 11 and the partition walls 12 on the substrate 10 to ashing using an oxygen plasma may include using a known oxygen plasma generator to generate an oxygen plasma and applying the oxygen plasma to the colored layers 11 and the partition walls 12 on the substrate 10.

The gas used to generate an oxygen plasma may be a mixture of oxygen and any of a variety of gases used for conventional plasma treatment. Examples of such gases include nitrogen gas, hydrogen gas, and helium gas. The ashing using an oxygen plasma may be performed under any appropriate conditions, which include, for example, a treatment time period in the range of 10 seconds to 20 minutes, preferably in the range of 20 seconds to 18 minutes, more preferably in the range of 30 seconds to 15 minutes.

Any method may be used to fill the gaps between the colored layers 11 with the resin, resin composition, cured resin, or cured resin composition. For example, the gaps may be filled with the resin or resin composition by a process that incudes applying, over the surface of the substrate 10, a liquid composition including a solvent and a resin or resin composition or a curable material; and then removing the solvent from the liquid composition filled in the gaps or curing the curable material filled in the gaps. The liquid composition is preferably applied over the surface of the substrate 10 by a method using a contact transfer applicator such as a roll coater, a reverse coater, or a bar coater or using a non-contact applicator such as a spinner (spin coater) or a curtain flow coater, more preferably by a method using a spinner. Alternatively, the liquid composition may be supplied only to the gaps by a printing method such as inkjet printing.

If a coating film is formed covering the surface of some portions of the colored layers 11 other than the gaps after the application of the liquid composition, the coating film on such portions may be removed by ashing or other means.

In the method described above, the material used to form the partition walls 12 is preferably a resin composition including (A) a resin and (B) hollow particles each having a shell including a resin, because such a resin composition can have a low refractive index, form bubbles with less variation in size and distribution, and be easily removed by ashing. This preferred resin composition will be described in detail later.

According to the method described above, the colored layers 11 and the partition walls 12 filled in the gaps between the colored layers 11 are formed on the substrate 10 so that a color filter including the colored layers 11 and the partition walls 12 is obtained.

### Second Embodiment

A second embodiment is directed to a method of manufacturing a color filter including:

a substrate; light-transmitting colored layers; and partition walls, the light-transmitting colored layers and the partition walls being provided on the substrate, each partition wall being disposed between and in contact with two of the colored layers adjacent to the partition wall to separate the adjacent colored layers with no gap between each of the adjacent colored layers and the partition wall, the partition wall having a refractive index lower than that of the colored layer, the method including:
forming a partition wall precursor film on the substrate; forming, on the precursor film, a mask at a position where each partition wall is to be formed;
subjecting the mask and the precursor film to an asking treatment to remove portions of the precursor film not covered by the mask and to retain, as a partition wall, each of portions of the precursor film covered by the mask; removing the mask; and
forming a colored layer in each of regions separated by the partition walls,
the precursor film including a bubble-containing resin, a bubble-containing resin composition, a bubble-containing cured resin, or a bubble-containing cured resin composition, the resin, the resin composition, the cured resin, or the cured resin composition having an inorganic content of 5% by mass or less.

In this regard, the material of the precursor film is the same as the material of the partition wall finally formed. Therefore, the material of the precursor film in the color filter manufacturing method according to the second embodiment is the same as the material of the partition wall described with respect to the color filter manufacturing method according to the first embodiment.

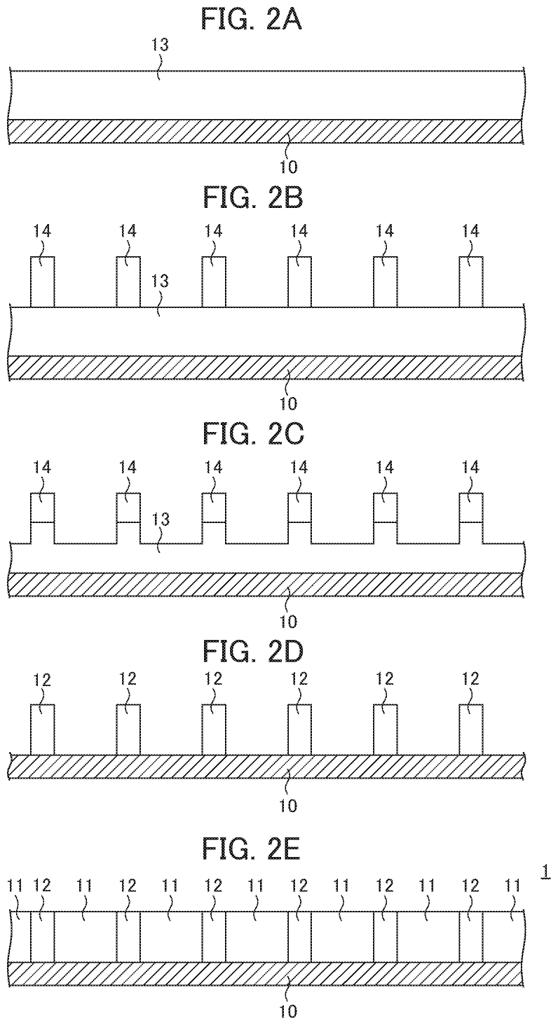

Hereinafter, the color filter manufacturing method according to the second embodiment will be described with reference to FIGS. 2A to 2E.

### <Step of Forming Precursor Film>

In the precursor film forming step, as shown in FIG. 2A, a precursor film 13 for partition walls 12 is first formed on a substrate 10. The liquid composition suitable for use in forming the partition walls 12 in the color filter manufacturing method according to the first embodiment may be used to form the precursor film 13. The precursor film 13 may be formed by applying the liquid composition to the substrate 10 and then removing the solvent from the coating film, if necessary, by heating or other means or curing the coating film by heating, exposure to light, or other methods.

The liquid composition is preferably applied to the substrate 10 by a method using a contact transfer applicator such as a roll coater, a reverse coater, or a bar coater, or using a non-contact applicator such as a spinner (spin coater), or a curtain flow coater, more preferably by a method using a spinner. Alternatively, the coating film may be formed by a printing method such as screen printing or inkjet printing.

The precursor film 13 may have a thickness similar to that of the colored layer 11. For example, the colored layer 11 and the precursor film 13 preferably have a thickness of 0.1 μm or more and 10 μm or less, more preferably 0.5 μm or more and 5 μm or less.

### <Step of Forming Mask>

In the mask forming step, as shown in FIG. 2B, a mask 14 is formed on the precursor film 13 and at a position where each partition wall 12 is to be formed. In the subsequent ashing step, only mask 14 covered portions of the precursor film 13 are protected from ashing and retained to form partition walls 12.

The mask 14 may be made of a material resistant to ashing or a material susceptible to ashing. In the former case, a stack (not shown) of the partition wall 12 and the mask 14 remains on the substrate after the subsequent ashing step. Only the mask 14 may be removed from such a stack by a treatment using a solvent, an alkali, or the like, so that the partition wall is formed on the substrate 10. The latter case will be described below in the Ashing Step section. It should be noted that FIG. 2C and FIG. 2D show a case where the mask 14 used is made of a material susceptible to ashing.

### <Ashing Step and Step of Removing Mask>

The ashing step includes subjecting the mask 14 and the precursor film 13 to an ashing treatment to remove portions of the precursor film 13 not covered by the mask 14 and to retain mask 14 covered portions of the precursor film 13 as partition walls 12.

The mask removing step includes removing the mask 14. The mask is removed after or simultaneously with the ashing step.

Hereinafter, a description will be given of a case where the mask 14 used is made of a material susceptible to ashing. In this case, the mask 14 is also gradually removed by ashing. As for the ashing step and the mask removing step, FIG. 2C shows the beginning of ashing performed on the mask 14 made of an ashing-susceptible material on the precursor film 13. FIG. 2C shows that not only the thickness of the precursor film 13 is reduced by ashing at positions not covered by the mask 14, but also the thickness of the mask 14 is reduced by ashing. As the ashing is continued from the state shown in FIG. 2C, the portions of the precursor film 13 not covered by the mask 14 are completely removed as shown in FIG. 2D, and the mask 14 is also removed by the ashing, so that only the mask 14 covered portions of the precursor film 13 are not removed by the ashing and are left to form partition walls 12.

The ashing may be performed under any conditions which allow formation of the partition walls 12 as desired. A preferred ashing treatment method may be a method using an oxygen plasma. The gas used to generate an oxygen plasma may be a mixture of oxygen and any of a variety of gases used for conventional plasma treatment. Examples of such gases include nitrogen gas, hydrogen gas, and helium gas. The ashing using an oxygen plasma may be performed under any appropriate conditions, which include, for example, a treatment time period in the range of 10 seconds to 20 minutes, preferably in the range of 20 seconds to 18 minutes, more preferably in the range of 30 seconds to 15 minutes.

### <Step of Forming Colored Layers>

In the colored layer forming step, as shown in FIG. 2E, a colored layer 11 is formed in each of the regions separated by the partition walls 12. The colored layer forming step typically includes forming colored layers 11 of red (R), green (G), and blue (B) in the regions separated by the partition walls 12. A method of forming such colored layers 11 may include forming colored layers of each color by a photolithographic process using photosensitive compositions for the three colors: red (R), green (G), and blue (B) so that the colored layer forming process is performed three times. In the regions separated by the partition walls 12, the colored layers 11 may also be formed by a printing method such as inkjet printing using ink compositions for forming the colored layers 11 of the three colors: red (R), green (G), and blue (B).

### <<Resin Composition>>

A resin composition including (A) a resin, (B) hollow particles each having a shell including a resin, and (S) an organic solvent is preferably used to form the partition walls or the precursor film in the color filter manufacturing methods according to the first and second embodiments. Hereinafter, essential and optional components of the preferred resin composition will be further described.

### <(A) Resin>

The resin (A) may be of any type. The resin (A) is preferably a (meth)acrylic resin because it has good workability during the process of forming the partition walls, including ashing. The (meth) acrylic resin preferably includes a structural unit represented by formula (a1) below and a structural unit represented by formula (a2) below since it can be more easily removed by ashing and can provide a crosslinked product having high resistance to solvents and chemicals when undergoing a curing reaction between epoxy groups. In the color filter manufacturing methods according to the first and second embodiments, therefore, the partition walls or precursor film formed preferably includes (A) a resin including a structural unit represented by formula (a1) below and a structural unit represented by formula (a2) below; and (B) hollow particles each having a shell including a resin.

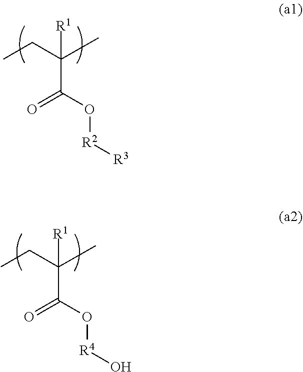

In the formulae (a1) and (a2), R¹ is each independently a hydrogen atom or a methyl group, R² is a single bond or an alkylene group having 1 or more and 5 or less carbon atoms, R³ is a monovalent organic group having 2 or more and 30 or less carbon atoms and having an epoxy group-containing structure, and R⁴ is a divalent hydrocarbon group.

Hereinafter, the structural unit represented by formula (a1) is also referred to as the “structural unit A1”, and the structural unit represented by formula (a2) is also referred to as the “structural unit A2”.

### [Structural Unit A1]

The structural unit A1 represented by formula (a1) contains an epoxy group in the R³ moiety, which allows the resin to have curing properties.

The alkylene group that may be the R² moiety has 1 or more and 5 or less carbon atoms, preferably 1 or more and 4 or less carbon atoms, more preferably 1 or more and 3 or less carbon atoms, still more preferably 1 or 2 carbon atoms. Specifically, the alkylene group may be methylene, ethylene, propylene, or butylene.

R³ is a monovalent organic group having 2 or more and 30 or less carbon atoms and having an epoxy group-containing structure. Examples of such an epoxy group also include alicyclic epoxy groups. The R³ moiety may also contain, in its structure, a hetero atom other than the oxygen atom in the epoxy group, or a halogen atom. The hetero atom may be nitrogen, sulfur, silicon, or the like, and the halogen atom may be fluorine, chlorine, bromine, or iodine.

The structural unit A1 can be formed, for example, by subjecting an epoxy group-containing (meth)acrylic ester to a polymerization reaction. The epoxy group-containing (meth)acrylic ester may be a chain aliphatic epoxy group-containing (meth)acrylic ester or an alicyclic epoxy group-containing (meth)acrylic ester as described below. The epoxy group-containing (meth)acrylic ester may also contain an aromatic group. The epoxy group-containing (meth)acrylic ester is preferably an aliphatic (meth)acrylic ester having a chain aliphatic epoxy group or an aliphatic (meth)acrylic ester having an alicyclic epoxy group. In the resin, the structural unit A1 may be present in blocks or at random.

Examples of the (meth)acrylic ester containing an aromatic group and an epoxy group include 4-glycidyloxyphenyl (meth) acrylate, 3-glycidyloxyphenyl (meth) acrylate, 2-glycidyloxyphenyl (meth) acrylate, 4-glycidyloxyphenylmethyl (meth) acrylate, 3-glycidyloxyphenylmethyl (meth) acrylate, and 2-glycidyloxyphenylmethyl (meth) acrylate.

Examples of the aliphatic (meth)acrylic ester having a chain aliphatic epoxy group include (meth)acrylic esters having a chain aliphatic epoxy group bonded to the oxy group (—O—) in the ester group (—O—CO—), such as epoxyalkyl (meth)acrylates and epoxyalkyloxyalkyl (meth)acrylates. The chain aliphatic epoxy group in such a (meth)acrylic ester may contain one or more oxy groups (—O—) in the chain. The number of carbon atoms in the chain aliphatic epoxy group is preferably, but not limited to, 3 or more and 20 or less, more preferably 3 or more and 15 or less, even more preferably 3 or more and 10 or less.

Specific examples of aliphatic (meth)acrylic esters having a chain aliphatic epoxy group include epoxyalkyl (meth)acrylates such as glycidyl (meth)acrylate, 2-methylglycidyl (meth)acrylate, 3,4-epoxybutyl (meth)acrylate, and 6,7-epoxyheptyl (meth)acrylate; and epoxyalkyloxyalkyl (meth)acrylates such as 2-glycidyloxyethyl (meth)acrylate, 3-glycidyloxy-n-propyl (meth) acrylate, 4-glycidyloxy-n-butyl (meth)acrylate, 5-glycidyloxy-n-hexyl (meth)acrylate, and 6-glycidyloxy-n-hexyl (meth) acrylate.

Specific examples of the aliphatic (meth)acrylic ester having an alicyclic epoxy group include compounds represented by formulae (a1-1) to (a1-15) below. In particular, compounds represented by formulae (a1-1) to (a1-5) below are preferred, and compounds represented by formulae (a1-1) to (a1-3) below are more preferred. In addition, some of the compounds may include positional isomers, in which the oxygen atom in the ester group may be bonded to the alicycle at any position other than that shown below.

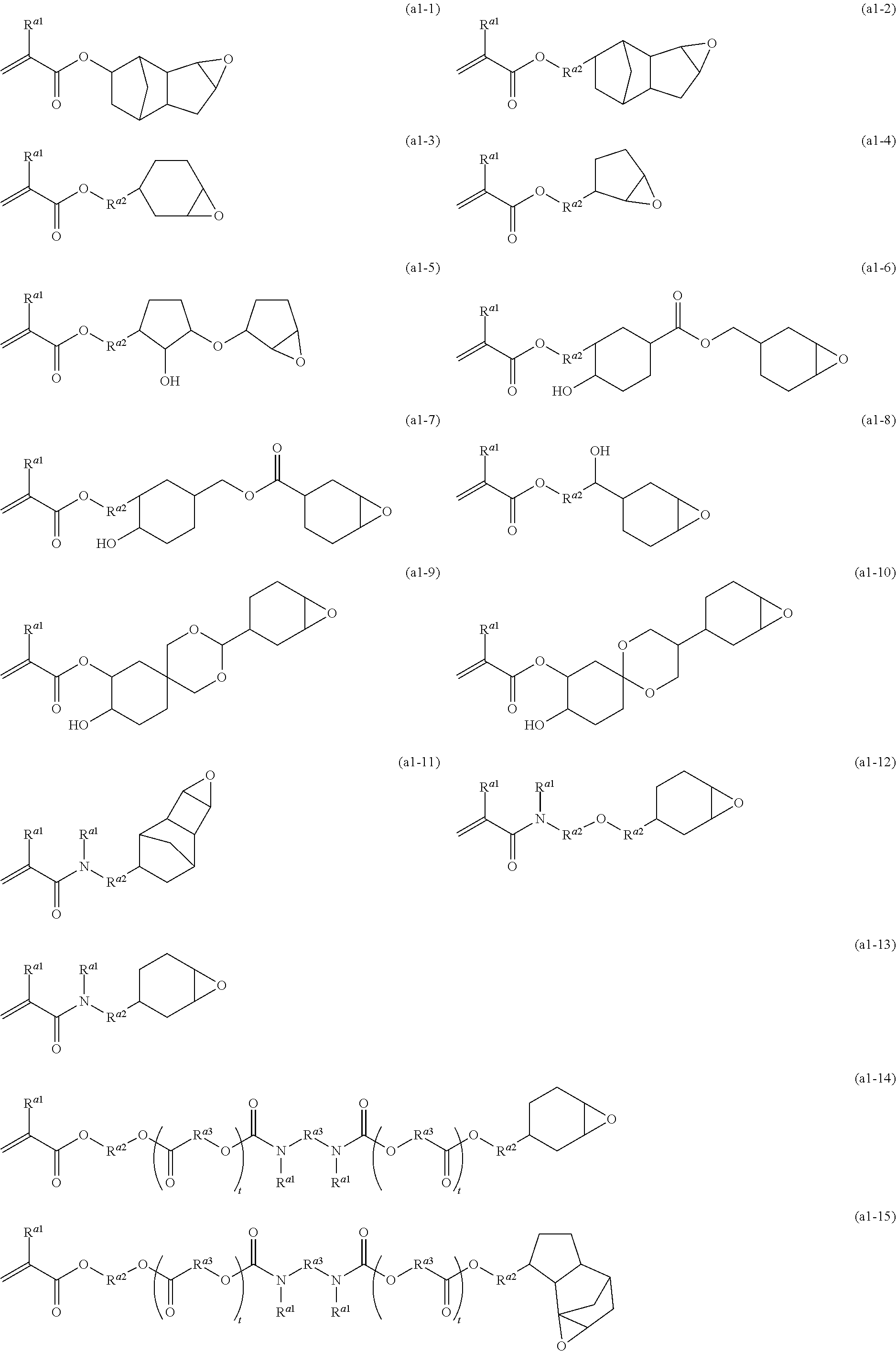

In the formulae, R^{a1} is a hydrogen atom or a methyl group, R^{a2} is a divalent aliphatic saturated hydrocarbon group having 1 or more and 6 or less carbon atoms, R^{a3} is a divalent hydrocarbon group having 1 or more and 10 or less carbon atoms, and t is an integer of 0 or more and 10 or less. R^{a2} is preferably a linear or branched alkylene group, such as a methylene group, an ethylene group, a propylene group, a tetramethylene group, an ethylethylene group, a pentamethylene group, or a hexamethylene group. Rai is preferably, for example, a methylene group, an ethylene group, a propylene group, a tetramethylene group, an ethylethylene group, a pentamethylene group, a hexamethylene group, a phenylene group, or a cyclohexylene group.

The structural unit A1 content of the resin (A) may be at any level in a range where the object of the present invention is not impaired. In view of curing properties, the resin (A) may have a structural unit A1 content of 20 mol % or more, preferably 20 mol % or more and 95 mol % or less, more preferably 30 mol % or more and 90 mol % or less, still more preferably 50 mol % or more and 85 mol % or less, based on the moles of all structural units in the resin.

### [Structural Unit A2]

The structural unit A2 is a structural unit represented by formula (a2) above.

In formula (a2), R⁴ is a divalent hydrocarbon group. The hydrocarbon group for R⁴ may be an aliphatic hydrocarbon group, an aromatic hydrocarbon group, or a hydrocarbon group having aliphatic and aromatic moieties. In view of the curing properties of the resin, R⁴ is preferably a divalent aliphatic hydrocarbon group. When R⁴ is a divalent aliphatic hydrocarbon group, the aliphatic hydrocarbon group may a linear, branched, or cyclic structure, or any combination of linear, branched, and cyclic structures. Preferably, it has a linear structure.

The hydrocarbon group for R⁴ may have any number of carbon atoms. When the hydrocarbon group is an aliphatic hydrocarbon group, it preferably has 1 or more and 20 or less carbon atoms, more preferably 2 or more and 10 or less carbon atoms, even more preferably 2 or more and 6 or less carbon atoms. When the hydrocarbon group is an aromatic group or a hydrocarbon group having aliphatic and aromatic moieties, it preferably has 6 or more and 20 or less carbon atoms, more preferably 6 or more and 12 or less carbon atoms.

Specific examples of the divalent aliphatic hydrocarbon group include a methylene group, an ethane-1,2-diyl group, an ethane-1,1-diyl group, a propane-1,3-diyl group, a propane-1,2-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group, a heptadecane-1,17-diyl group, an octadecane-1,18-diyl group, a nonadecane-1,19-diyl group, and an icosane-1,20-diyl group. In particular, preferred are methylene, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, decane-1,10-diyl, undecane-1,11-diyl, dodecane-1,12-diyl, tridecane-1,13-diyl, tetradecane-1,14-diyl, pentadecane-1,15-diyl, hexadecane-1,16-diyl, heptadecane-1,17-diyl, octadecane-1,18-diyl, nonadecane-1,19-diyl, and icosan-1,20-diyl group; more preferred are methylene, ethane-1,2-diyl, propane-1,3-diyl, butane-1,4-diyl, pentane-1,5-diyl, hexane-1,6-diyl, heptane-1,7-diyl, octane-1,8-diyl, nonane-1,9-diyl, and decane-1,10-diyl; and still more preferred are ethane-1,2-diyl, propane-1,3-diyl, butane-1,4-diyl, pentane-1,5-diyl, and hexane-1,6-diyl.

Specific examples of the divalent aromatic hydrogen group include a p-phenylene group, a m-phenylene group, an o-phenylene group, a naphthalene-1,4-diyl group, a naphthalene-2,6-diyl group, and a naphthalene-2,7-diyl group, in which a p-phenylene group and a m-phenylene group are preferred, and a p-phenylene group is more preferred.

The structural unit A2 may be incorporated into the resin by copolymerizing a (meth)acrylic ester represented by formula (a-II) below with a monomer for forming any other structural unit. In the resin, the structural units A2 may be present in blocks or at random.

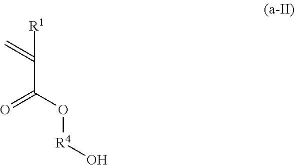

In formula (a-II), R¹ and R⁴ have the same meanings as defined for formula (a2).

Specific preferred examples of the (meth)acrylic ester for forming the structural unit A2 include 2-hydroxyethyl acrylate, 2-hydroxyethyl methacrylate, 3-hydroxypropyl acrylate, 3-hydroxypropyl methacrylate, 4-hydroxybutyl acrylate, 4-hydroxybutyl methacrylate, 4-hydroxyphenyl acrylate, 4-hydroxyphenyl methacrylate, 3-hydroxyphenyl acrylate, and 3-hydroxyphenyl methacrylate. In particular, preferred are 2-hydroxyethyl acrylate, 2-hydroxyethyl methacrylate, 4-hydroxyphenyl acrylate, and 4-hydroxyphenyl methacrylate.

The structural unit A2 content of the resin (A) may be at any level in a range where the object of the present invention is not impaired. In view of curing properties, the resin (A) preferably has a structural unit A2 content of 3 mol % or more and 40 mol % or less, more preferably 5 mol % or more and 30 mol % or less, still more preferably 10 mol % or more and 25 mol % or less, based on the moles of all structural units in the resin.

### [Other Structural Units]

While the resin (A) may include only the structural units A1 and A2, the resin (A) may include any other structural unit in addition to the structural units A1 and A2 as long as the object of the present invention is not impaired.

Examples of other structural units include structural units derived from (meth)acrylic esters other than those listed above. Such a (meth) acrylic ester may be a compound represented by formula (a-III) below, which may be of any type that does not impair the object of the present invention.

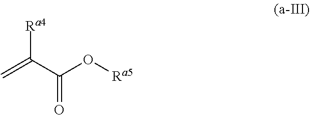

In formula (a-III) above, Rao is a hydrogen atom or a methyl group. R^{a5} is an organic group free of any active hydrogen-containing group. The organic group is preferably a carbon atom-containing group, more preferably a group including one or more carbon atoms and one or more atoms selected from the group consisting of H, O, S, Se, N, B, P, Si, and halogen atoms. The carbon atom-containing group may have any number of carbon atoms, preferably 1 or more and 50 or less carbon atoms, more preferably 1 or more and 20 or less carbon atoms. Examples of active hydrogen-containing groups include a hydroxyl group, a mercapto group, an amino group, and a carboxy group. The organic group may contain a heteroatom, a bond, or a substituent other than those in a hydrocarbon group. The organic group may also be linear, branched, or cyclic.

The organic group for R^{a5} may contain any substituent other than a hydrocarbon group as long as the present invention remains effective. Examples of substituents include a halogen atom, an alkylthio group, an arylthio group, a cyano group, a silyl group, an alkoxy group, an alkoxycarbonyl group, a nitro group, a nitroso group, an acyl group, an acyloxy group, an alkoxyalkyl group, an alkylthioalkyl group, an aryloxyalkyl group, an arylthioalkyl group, and an N,N-disubstituted amino group (—NRR′ in which R and R′ are each independently a hydrocarbon group). Hydrogen atoms in the above substituents may be replaced by hydrocarbon groups. Further, hydrocarbon groups in the substituents may be linear, branched or cyclic.

R^{a5} is preferably an alkyl group, an aryl group, an aralkyl group, or a heterocyclic group. These groups may be substituted with a halogen atom, an alkyl group, or a heterocyclic group. In addition, when these groups contain an alkylene moiety, the alkylene moiety may be interrupted by an ether bond, a thioether bond, or an ester bond.

When the alkyl group is linear or branched, it preferably has 1 or more and 20 or less carbon atoms, more preferably 1 or more and 15 or less carbon atoms, even more preferably 1 or more and 10 or less carbon atoms. Preferred examples of the alkyl group include methyl, ethyl, n-propyl, isopropyl, n-butyl, isobutyl, sec-butyl, tert-butyl, n-pentyl, isopentyl, sec-pentyl, tert-pentyl, n-hexyl, n-heptyl, n-octyl, isooctyl, sec-octyl, tert-octyl, n-nonyl, isononyl, n-decyl, and isodecyl groups.

When R^{as} is an alicyclic group or a group containing an alicyclic group, preferred examples of the alicyclic group include monocyclic alicyclic groups such as cyclopentyl and cyclohexyl groups; and polycyclic alicyclic groups such as adamantyl, norbornyl, isobornyl, tricyclononyl, tricyclodecyl, and tetracyclododecyl groups.

Examples of monomers for forming other structural units, other than the (meth)acrylic esters, include allyl compounds, vinyl ethers, vinyl esters, and styrene compounds. These monomers may be used alone, or two or more of them may be used in combination.

Allyl compounds include allyl esters such as allyl acetate, allyl caproate, allyl caprylate, allyl laurate, allyl palmitate, allyl stearate, allyl benzoate, allyl acetoacetate, and allyl lactate; (allyloxy)ethanol; etc.

Vinyl ethers include alkyl vinyl ethers such as hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethyl propyl vinyl ether, 2-ethylbutyl vinyl ether, diethylene glycol vinyl ether, dimethylaminoethyl vinyl ether, diethylaminoethyl vinyl ether, butylaminoethyl vinyl ether, benzyl vinyl ether, and tetrahydrofurfuryl vinyl ether; vinyl aryl ethers such as vinyl phenyl ether, vinyl tolyl ether, vinyl chlorophenyl ether, vinyl-2,4-dichlorophenyl ether, vinyl naphthyl ether, and vinyl anthranil ether; etc.

Vinyl esters include vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl-p-phenylbutyrate, vinyl benzoate, vinyl chlorobenzoate, vinyl tetrachlorobenzoate, and vinyl naphthoate.

Styrene compounds include styrene; alkylstyrenes such as methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, and acetoxymethylstyrene; alkoxystyrenes such as methoxystyrene, 4-methoxy-3-methylstyrene, and dimethoxystyrene; halostyrenes such as chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, and 4-fluoro-3-trifluoromethylstyrene; etc.

When the resin (A) contains any other structural unit in addition to the structural units A1 and A2, the total content of the structural units A1 and A2 in the resin (A) is preferably 80 mol % or more, more preferably 90 mol % or more, even more preferably 95 mol % or more, based on the moles of all structural units in the resin (A). [Method for Producing the Resin (A)]

The resin (A) described above may be produced by any method. In general, the resin (A) may be obtained by a process that includes mixing predetermined amounts of monomers for forming the structural units A1 and A2 and a predetermined amount(s) of any other optional other monomer(s) for forming any other optional structural unit(s) and then polymerizing the monomers in a suitable solvent in the presence of a polymerization initiator, for example, in the temperature range of 50° C. to 120° C. The resin (A) is often obtained in the form of an organic solvent solution. Such a solution of the resin (A) may be directly used to form the resin composition, or the resin (A) may be precipitated as a solid polymer from such a solution and then used to form the resin composition.

The resin (A) obtained by the process preferably has a weight average molecular weight of 5,000 or more, more preferably 7,500 or more and 100,000 or less, even more preferably 10,000 or more and 80,000 or less. The weight average molecular weight may be the polystyrene-equivalent molecular weight measured by GPC. The resin having a relatively large weight average molecular weight can easily form a cured product having high resistance to solvents and thermal decomposition.

The content of the resin (A) in the composition is preferably 20% by mass or more and 90% by mass or less, more preferably 30% by mass or more and 85% by mass or less, even more preferably 40% by mass or more and 80% by mass or less, based on the total mass of solids in the composition. The composition with the resin content in such a range can easily form a cured product with high solvent resistance.

### <(B) Hollow Particles>

The hollow particles (B) in the resin composition according to the embodiment are characterized by having a shell including a resin.

The hollow particles (B) each include a shell as an outer crust and an inner void. The shell may be a single layer or a multilayer structure. The shell may include a plurality of layers each including different resin components. The hollow particles (B) may have undergone a known surface treatment for enhancing the affinity for the resin (A) and so on.

Specific examples of the hollow particles (B) include polyester-based porous particles obtained by suspension polymerization of a W/O/W emulsion, acrylic porous particles, styrene-acrylic-based hollow latexes produced by seed polymerization, and thermally expandable microcapsules such as vinylidene chloride-acrylonitrile-based microcapsules and acrylonitrile-based microcapsules. In addition, hollow particles such as those disclosed in WO 2018/051794 and WO 2017/163439 can be advantageously used, and commercially available hollow particles may also be used, such as Techpolymer (registered trademark) NH (Sekisui Kasei Co., Ltd.).

The average particle diameter of the hollow particles (B) may be appropriately set in consideration of the refractive index and other properties of the partition wall, and may be, for example, in the range of 20 nm to 300 nm, preferably in the range of 25 nm to 200 nm, more preferably in the range of 30 nm to 150 nm. The thickness of the shell layers in the hollow particles (B) may be set, for example, in the range of 0.03×X to 0.60×X, preferably in the range of 0.05×X to 0.50×X, more preferably in the range of 0.10×X to 0.40×X, in which X represents the average particle diameter [nm] of the hollow particles (B). More typically, the average particle diameter of the hollow particles (B) is set in the range of 30 nm to 150 nm, and the thickness of the shell layers in the hollow particles (B) is set in the range of 5 nm to 30 nm. Setting the diameter and thickness in such a range allows a good balance between the mechanical strength and low refractive index to be obtained when the resin composition is cured. The average particle size of the hollow particles (B) may be measured using, for example, a dynamic light scattering method. The thickness of the shell layers in the hollow particles (B) may be measured by observing the cross-sections of 50 randomly selected particles.

The content of the hollow particles (B) in the resin composition is preferably 10% by mass or more and 80% by mass or less, more preferably 15% by mass or more and 70% by mass or less, even more preferably 20% by mass or more and 60% by mass or less, based on the total mass of solids in the resin composition. Setting the content in such a range makes it easy to obtain a cured product having high solvent resistance.

### <(S) Organic Solvent>

The resin composition suitable for use in forming the partition walls or the precursor film contains (S) an organic solvent. Preferred examples of the organic solvent (S) include monoalkyl ethers of glycols, such as ethylene glycol monomethyl ether, ethylene glycol monoethyl ether, propylene glycol monomethyl ether, propylene glycol monoethyl ether, diethylene glycol monomethyl ether, diethylene glycol monoethyl ether, propylene glycol monopropyl ether, and propylene glycol monobutyl ether; monoalkyl ether acetates of glycols, such as ethylene glycol monomethyl ether acetate, ethylene glycol monoethyl ether acetate, propylene glycol monomethyl ether acetate, propylene glycol monoethyl ether acetate, propylene glycol monopropyl ether acetate, and propylene glycol monobutyl ether acetate; aromatic solvents such as toluene and xylene; ketones such as acetone, methyl ethyl ketone, 2-heptanone, cyclopentanone, and cyclohexanone; and esters such as ethyl acetate, butyl acetate, ethyl ethoxyacetate, ethyl hydroxyacetate, 3-methoxybutyl acetate, 3-methyl-3-methoxybutyl acetate, ethyl 2-hydroxypropionate, ethyl 2-hydroxy-2-methylpropionate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl lactate, butyl lactate, and y-butyrolactone.

In view of the leveling properties of the coating film resulting from the application of the resin composition, preferred examples of the organic solvent (S) include propylene glycol monomethyl ether, propylene glycol monomethyl ether acetate, 2-heptanone, cyclopentanone, cyclohexanone, ethyl lactate, and butyl lactate, and more preferred examples include propylene glycol monomethyl ether, propylene glycol monomethyl ether acetate, 2-heptanone, cyclopentanone, and cyclohexanone. In the resin composition, the organic solvent (S) may be a single solvent or a mixture of two or more solvents.

To form the resin composition, the organic solvent (S) may be used in any amount which is appropriately determined taking into account viscosity and other properties depending on the use of the resin composition. The content of the organic solvent (S) in the resin composition is preferably set such that the resin composition has a solid concentration of 1% by mass or more, more preferably 2% by mass or more, still more preferably 3% by mass or more. Further, the content of the organic solvent (S) is preferably set such that that the resin composition has a solid concentration of 45% by mass or less, more preferably 30% by mass or less, still more preferably 25% by mass or less.

Hereinafter, optional components of the resin composition will be described.

### <(C) Epoxy Compound>

The resin composition suitable for use in forming the partition walls or precursor film may contain an epoxy compound (C). It should be noted that the epoxy compound (C) does not correspond to the component (A).

The epoxy compound (C) may be any of various epoxy compounds widely known in the art. The epoxy compound may have any appropriate molecular weight. The epoxy compound is preferably a polyfunctional epoxy compound having two or more epoxy groups per molecule, which can easily form a cured film having a high level of heat resistance, chemical resistance, mechanical properties, and other properties.

The polyfunctional epoxy compound may be of any type having two or more functional groups. Examples of the polyfunctional epoxy compound include bifunctional epoxy resins such as bisphenol A epoxy resins, bisphenol F epoxy resins, bisphenol S epoxy resins, bisphenol AD epoxy resins, naphthalene epoxy resins, and biphenyl epoxy resins; glycidyl ester epoxy resins such dimer acid glycidyl esters and triglycidyl esters; glycidyl amine epoxy resins such as tetraglycidylaminodiphenylmethane, triglycidyl-p-aminophenol, tetraglycidylmetaxylylenediamine, and tetraglycidylbisaminomethylcyclohexane; heterocyclic epoxy resins such as triglycidyl isocyanurate; trifunctional epoxy resins such as fluoroglycinol triglycidyl ether, trihydroxybiphenyl triglycidyl ether, trihydroxyphenylmethane triglycidyl ether, glycerin triglycidyl ether, 2-[4-(2,3-epoxypropoxy)phenyl]-2-[4-[1,1-bis[4-(2,3-epoxypropoxy)phenyl]ethyl]propane, and 1,3-bis[4-[1-[4-(2,3-epoxypropoxy)phenyl]-1-[4-[1-[4-(2,3-epoxypropoxy)phenyl]-1-methylethyl]phenyl]ethyl]phenoxy]-2-propanol; and tetrafunctional epoxy resins such as tetrahydroxyphenylethane tetraglycidyl ether, tetraglycidyl benzophenone, bisresorcinol tetraglycidyl ether, and tetraglycidoxybiphenyl.

The polyfunctional epoxy compound is also preferably an alicyclic epoxy compound, which can form a cured product with high hardness. Specific examples of the alicyclic epoxy compound include 2-(3,4-epoxycyclohexyl-5,5-spiro-3,4-epoxy)cyclohexane-meta-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylcyclohexanecarboxylate, s-caprolactone-modified 3,4-epoxycyclohexylmethyl-3′,4′-epoxycyclohexanecarboxylate, trimethylcaprolactone-modified 3,4-epoxycyclohexylmethyl-3′,4′-epoxycyclohexanecarboxylate, P-methyl-5-valerolactone-modified 3,4-epoxycyclohexylmethyl-3′,4′-epoxycyclohexanecarboxylate, methylenebis(3,4-epoxycyclohexane), di(3,4-epoxycyclohexylmethyl)ether of ethylene glycol, ethylenebis(3,4-epoxycyclohexanecarboxylate), dioctyl epoxycyclohexahydrophthalate, di-2-ethylhexyl epoxycyclohexahydrophthalate, and epoxy resins having tricyclodeceneoxide groups. When the resin composition contains the epoxy compound (C), the content of the epoxy compound (C) is preferably 1 part by mass or more and 100 parts by mass or less, more preferably 3 parts by mass or more and 50 parts by mass or less, based on 100 parts by mass of the resin (A).

### <<(D) Surfactant>>

The surfactant may be a fluorine atom-containing surfactant, or a silicon atom-containing surfactant. The fluorine atom-containing surfactant is preferably a fluorosurfactant having an alkylene oxide chain. The silicon atom-containing surfactant is preferably a polysiloxane surfactant having an alkylene oxide chain. Preferred examples of the fluorine atom-containing surfactant include PolyFox series such as PF-636, PF-6320, PF-656, and PF-6520 (all trade names, available from OMNOVA Solutions Inc.). Preferred examples of the silicon atom-containing surfactant include BYK-307, BYK-333, and BYK-378 (all trade names, available from BYK-Chemie GmbH). When the resin composition contains the surfactant (D), the content of the surfactant (D) is preferably 0.01 parts by mass or more and 1 part by mass or less based on 100 parts by mass of the resin (A). More preferably, it is 0.03 parts by mass or more and 0.8 parts by mass or less.

The resin composition suitable for use in forming the partition walls or precursor film may further contain various additives as long as the object of the present invention is not impaired. Examples of additives include a crosslinking agent, an ultraviolet absorber, a sensitizer, a plasticizer, an antioxidant, a light stabilizer, an adhesion aid, an acid generator, and a radical generator.

### [Method for Preparing Resin Composition]

The resin composition suitable for use in forming the partition walls or precursor film may be prepared by mixing and stirring the above components by a conventional method. The components may be mixed and stirred using a dissolver, a homogenizer, a three roll mill, or other devices. After the components are mixed uniformly, the resulting mixture may be filtered using a mesh, a membrane filter, or the like.

### [Cured Product]

When subjected to a heating step, the resin composition is converted into a cured product. The cured product preferably has a refractive index of 1.50 or less, more preferably 1.48 or less, even more preferably 1.45 or less. The lower limit of the refractive index is, for example, 1.20 or more and is not particularly limited.

When heated, the resin including the structural units A1 and A2 described above gives a crosslinked product having high resistance to solvents and chemicals. The heating temperature may be at any level that does not cause excessive damage to the substrate. The upper limit of the heating temperature is, for example, preferably 300° C. or less, more preferably 280° C. or less. The lower limit of the heating temperature is preferably 120° C. or more, more preferably 130° C. or more.

### EXPLANATION OF REFERENCE NUMERALS

1: Color filter
10: Substrate
11: Colored layer
12: Partition wall
13: Precursor film
14: Mask

What is claimed is:

1. A method of manufacturing a color filter comprising a substrate, light-transmitting colored layers, and partition walls, wherein the light-transmitting colored layers and the partition walls are provided on the substrate, each partition wall is disposed between and in contact with two of the colored layers adjacent to the partition wall to separate the adjacent colored layers with no gap between each of the adjacent colored layers and the partition wall, wherein the partition wall has a refractive index lower than that of the colored layer, the method comprising:
forming a plurality of colored layers such that the plurality of colored layers are arranged with gaps each at a position where a partition wall is to be formed; and
filling the gaps with a bubble-containing resin, a bubble-containing resin composition, a bubble-containing cured resin, or a bubble-containing cured resin composition to form partition walls,
wherein the resin, the resin composition, the cured resin, or the cured resin composition have an inorganic content of 5% by mass or less.

2. The method according to claim 1, wherein the partition walls comprise a resin composition comprising (A) a resin and (B) hollow particles each having a shell comprising a resin, or the partition walls comprise a cured product of the resin composition.

3. The method according to claim 2, wherein the resin (A) comprises a structural unit represented by formula (a1) and a structural unit represented by formula (a2): 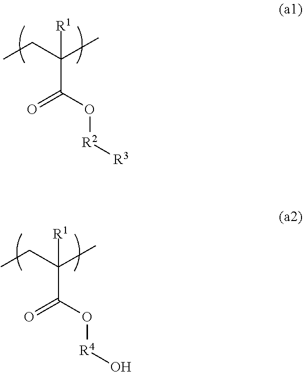
wherein each R¹ is independently a hydrogen atom or a methyl group, R² is a single bond or an alkylene group having 1 or more and 5 or less carbon atoms, R³ is a monovalent organic group having 2 or more and 30 or less carbon atoms and having an epoxy group-containing structure, and R⁴ is a divalent hydrocarbon group.

4. The method according to claim 3, wherein the resin has a content of the structural unit represented by formula (a1) of 20 mol % or more based on the moles of all structural units including the structural units represented by formulae (a1) and (a2) in the resin.

5. The method according to claim 3, wherein the resin has a content of the structural unit represented by formula (a2) of 3 mol % or more and 40 mol % or less based on the moles of all structural units including the structural units represented by formulae (a1) and (a2) in the resin.

6. The method according to claim 2, wherein the hollow particles (B) have an average particle diameter of 20 nm or more and 300 nm or less.

7. The method according to claim 2, wherein the resin composition has a content of the resin (A) of 20% by mass or more and 90% by mass or less.

8. The method according to claim 2, wherein the resin composition has a content of the hollow particles (B) of 10% by mass or more and 80% by mass or less.

9. A method of manufacturing a color filter comprising a substrate, light-transmitting colored layers, and partition walls, wherein the light-transmitting colored layers and the partition walls are provided on the substrate, each partition wall is disposed between and in contact with two of the colored layers adjacent to the partition wall to separate the adjacent colored layers with no gap between each of the adjacent colored layers and the partition wall, and the partition wall has a refractive index lower than that of the colored layer, the method comprising:
forming a partition wall precursor film on the substrate;
forming, on the precursor film, a mask at a position where each partition wall is to be formed;
subjecting the mask and the precursor film to an asking treatment to remove portions of the precursor film not covered by the mask and to retain, as a partition wall, each of portions of the precursor film covered by the mask;
removing the mask; and
forming a colored layer in each of regions separated by the partition walls,
wherein the precursor film comprises a bubble-containing resin, a bubble-containing resin composition, a bubble-containing cured resin, or a bubble-containing cured resin composition,
and the resin, the resin composition, the cured resin, or the cured resin composition have an inorganic content of 5% by mass or less.

10. The method according to claim 9, wherein the precursor film comprises a resin composition comprising (A) a resin and (B) hollow particles each having a shell comprising a resin, or the partition walls or the precursor film comprises a cured product of the resin composition.

11. The method according to claim 10, wherein the resin (A) comprises a structural unit represented by formula (a1) and a structural unit represented by formula (a2): 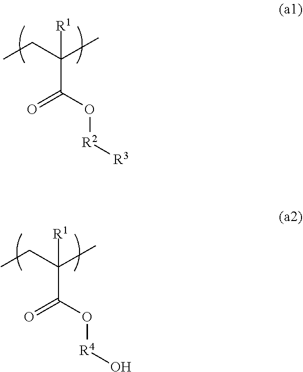
wherein each R¹ is independently a hydrogen atom or a methyl group, R² is a single bond or an alkylene group having 1 or more and 5 or less carbon atoms, R³ is a monovalent organic group having 2 or more and 30 or less carbon atoms and having an epoxy group-containing structure, and R⁴ is a divalent hydrocarbon group.

12. The method according to claim 11, wherein the resin has a content of the structural unit represented by formula (a1) of 20 mol % or more based on the moles of all structural units including the structural units represented by formulae (a1) and (a2) in the resin.

13. The method according to claim 11, wherein the resin has a content of the structural unit represented by formula (a2) of 3 mol % or more and 40 mol % or less based on the moles of all structural units including the structural units represented by formulae (a1) and (a2) in the resin.

14. The method according to claim 10, wherein the hollow particles (B) have an average particle diameter of 20 nm or more and 300 nm or less.

15. The method according to claim 10, wherein the resin composition has a content of the resin (A) of 20% by mass or more and 90% by mass or less.

16. The method according to claim 10, wherein the resin composition has a content of the hollow particles (B) of 10% by mass or more and 80% by mass or less.

17. A color filter comprising a substrate, light-transmitting colored layers, and partition walls, wherein the light-transmitting colored layers and the partition walls are provided on the substrate, each partition wall is disposed between and in contact with two of the colored layers adjacent to the partition wall to separate the adjacent colored layers with no gap between each of the adjacent colored layers and the partition wall, the partition wall has a refractive index lower than that of the colored layer, the partition walls comprise a bubble-containing resin, a bubble-containing resin composition, a bubble-containing cured resin, or a bubble-containing cured resin composition, and the resin, the resin composition, the cured resin, or the cured resin composition have an inorganic content of 5% by mass or less.

18. The color filter according to claim 17, wherein the partition walls comprise a resin composition comprising (A) a resin and (B) hollow particles each having a shell comprising a resin, or the partition walls comprise a cured product of the resin composition.

19. The color filter according to claim 18, wherein the resin (A) comprises a structural unit represented by formula (a1) and a structural unit represented by formula (a2): 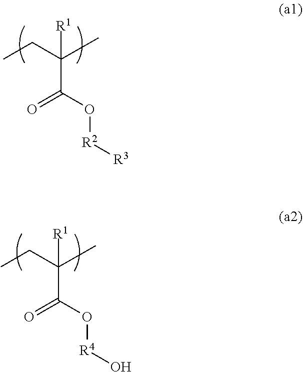
wherein each R¹ is independently a hydrogen atom or a methyl group, R² is a single bond or an alkylene group having 1 or more and 5 or less carbon atoms, R³ is a monovalent organic group having 2 or more and 30 or less carbon atoms and having an epoxy group-containing structure, and R⁴ is a divalent hydrocarbon group.
